(19) United States
(12) Patent Application Publication
(10) Pub. No.: US 2023/0163735 A1
(43) Pub. Date: May 25, 2023

(54) METHOD AND SYSTEM FOR INCREASING EFFICIENCY IN AUDIO AMPLIFIERS

(71) Applicant: Juliano Anflor, Gravataí (BR)

(72) Inventor: Juliano Anflor, Gravataí (BR)

(21) Appl. No.: 17/423,791

(22) PCT Filed: Jun. 9, 2021
(86) PCT No.: PCT/BR2021/050251

§ 371 Date: Jul. 16, 2021

(30) Foreign Application Priority Data
Feb. 5, 2021 (BR) BR 102021002247-7

(51) Int. Cl. H03F 3/217; H04R 3/00

(52) U.S. Cl. CPC H03F 3/2171; H04R 3/00; H04R 2203/00; H03F 2200/03

(57) ABSTRACT

The audio amplification system comprises a power supply (100) connected to a feedback circuit (107), which is connected to the amplifier output filter, so that the power supply voltage (100) dynamically adjusts to the amplifier output voltage. Connected to the power supply (100) and mosfets (102) is a capacitor (108) with the function of stabilizing the power supply voltage (100). The system also comprises a control circuit (106), in which the mosfets (102) are connected, which connect to the output filter through an inductor (103) and a capacitor (104). The amplifier output (101) involves a speaker (105).

### TECHNICAL SECTOR

The present invention belongs, in general, to the technological sector of electronic devices and refers, more specifically, to the audio amplifier sector, its purpose being to increase the efficiency and reduce stand-by consumption of class D amplifiers through the constant and dynamic variation of the supply voltage from the source based on the output voltage of the amplifier, which generates the audio sent to the speaker. The variation of the supply voltage from the source based on the amplifier output voltage reduces energy losses in switching the mosfets and in the output filter, composed of an inductor and a capacitor. In this way, the efficiency of the audio amplifier is enhanced without increasing its complexity and the production cost of the system.

### STATE OF THE ART

Audio amplifiers do not usually have variable power voltage. However, there are two classes that differ by operating with more than one power supply or by having a variable power supply.

Class H amplifiers, represented by the electrical circuit in FIG. 2, have two or more power supplies—(200), (201), (202) and (203)—with different voltages and which are selected by a control (204) according to the output power of the amplifier. When output power is low, power supplies with lower voltages (201) and (202) are selected using low-power transistors (206) and (207). As the power rises, on the other hand, the power supplies (200) and (203), with higher voltages, are selected through the transistors (205) and (208) thus increasing the efficiency of the amplifier. The problem with the Class H amplifier is that in order to achieve high efficiency, several power supplies with different voltages are required, so that the more power supplies are added to increase efficiency, the more complex and expensive the amplifier is.

Another type of amplifier with variable source is the amplifier of class G. In this system, whose variation of audio signals and the source is represented in FIG. 3, a single variable voltage source—(301) and (303)—provides power to the amplifier. However, the power supply system of the source is complex, since it needs to vary the operating voltage at the same rate of variation as the audio signal (302). Because the audio signal can reach 20 KHz, which is within the audible frequency range, the source voltage would need to range from zero to maximum voltage at only 50 ps (50 millionths of a second). Thus, the implementation of Class G amplifiers becomes expensive and difficult to obtain a fast and effective response. In case the response is not fast enough, parts of the audio signal (302) will not be played back by the amplifier. In some cases, Class G amplifiers are used only for the limited low frequency range of the audio spectrum, due to the complexity of this source, which limits its use. Moreover, this source (301) and (303) does not allow to contain a high impedance capacitor, because, if it did, it would not respond quickly enough to follow the rate of variation of the audio signal (302). Thus, there is a need for the Class G amplifier source to be much more powerful than a conventional source that contains a large capacitor as a buffer (accumulator) of power, providing it to the amplifier when there are current surges drained by the amplifier.

Conventional Class D amplifiers, whose circuit is schematically represented by FIG. 4, are basically composed of a control circuit (306), output transistors (mosfets-302), output filter with an inductor (303) and a capacitor (304), a non-variable power supply (300), equipped with feedback (307), the amplifier output (301) and the speaker (305). Feedback (307) provides the source (300) with its own output voltage in order to keep the voltage stable at a predetermined fixed value. Theoretically, class D amplifiers achieve 100% efficiency, since transistors (302) work in a switched way, that is, now connected, with maximum current and voltage drop in the null terminals, now open, with maximum voltage and null current. In both cases, the resulting dissipated power would be null, as the power varies with the product of the voltage by the current. The problem lies in the fact that transistors (302) are not ideal. When connected, the transistors (302) have an internal resistance, causing a voltage drop, which results in dissipated power in this state. Moreover, the switching speed is not infinite (response time not null) and, during the transition between the connected and open states, the transistor operates for a short period in linear regime, with non-null voltage and current, generating energy loss. The loss of energy by switching (P_{Switching}) is proportional to the power voltage (Vᵢₙ), the current (l₀), the operating frequency f (fₒₚₑᵣₐₜᵢₒₙ) and the response time (tᵣₑₛₚₒₙₛₑ), according to Equation 1.

P_{switching}=0.5×Vᵢₙ×l₀×(tᵣₑₛₚₒₙₛₑ)×fₒₚₑᵣₐₜᵢₒₙ Equation 1

In addition to loss by switching, the loss by parasitic capacitance occurs in the mosfets (302). Every time the mosfet (302) changes state, a capacitor, whose capacitance is around 1000 pF, needs to be charged and discharged, generating energy loss in the form of heat. The energy loss (called Coss, P_{Coss}) is proportional to the input supply voltage (V_{ds}), the frequency of mosfet switching (f_{switching}) and parasitic capacitances (Cₒₛₛ and C_{L}, according to Equation 2.

$${P}_{Coss} = 0.5 \times {f}_{switching} \times ( {C}_{oss} + {C}_{L} ) \times {V}_{ds}^{2} \qquad Equation 2$$

Similarly, the output filter (303) and (304), whose function is to filter the square wave generated by switching the transistors (mosfets-302), is not ideal. The inductor (303) has a core that can be made of ferrite, iron powder or other material that denotes energy losses, due to the alternating magnetic field generated by the AC voltage of the oscillation of the amplifier output transistors, in order to generate the pulse width modulation (PWM), typical of class D amplifiers. This loss is known as core loss and is proportional to the AC voltage. Thus, a field generated from 500 G to 100 KHz generates a loss of 340 mW/cm³, while a field generated from 250 G to 100 KHz generates a loss of about 70 mW/cm³.

Currently, conventional D-class amplifier designs have reached a maturity point so that efficiency is so high that there is no opportunity for improvement. This is due to the evolution of the techniques employed in the construction of amplifiers and also of electronic components, especially in transistors or mosfets (302) that, over the years, have evolved significantly, allowing class D amplifiers to reach up to 95% efficiency.

The new energy regulations require the continuous reduction of energy waste, both for the consumer market and for the automotive market. Thus, it becomes increasingly difficult to reach the levels required by the regulations, as the options for improvements and innovations are increasingly scarce.

### NOVELTIES AND OBJECTIVE OF THE INVENTION

The objective of the present invention is a method and an electronic system that allows increased efficiency in audio amplifiers, which effectively solves the limitations of the state of the art mentioned above: consumption and low efficiency.

The innovation claimed is to dynamically adjust the voltage of the amplifier power supply as a function of the amplifier output voltage through a feedback. Dynamic adjustment of the source voltage reduces switching losses in the mosfets and output inducer, increasing efficiency at low and medium power and reducing stand-by energy consumption.

The electronic amplification system comprises a source, in which a feedback component is connected, which is connected to the amplifier output, so that the amplifier output is read and the voltage adjustment is adjusted at the source. Thus, there is the constant adjustment of the voltage of the power supply based on the output voltage of the amplifier.

### ADVANTAGES OF INVENTION

The electronic amplification system, the object of the present invention, results in the following advantages over the amplifiers from the state of the art, especially class D amplifiers:
it reduces energy losses in mosfet switching and in the output filter;
it reduces stand-by consumption of Class D amplifiers;
it increases the efficiency of Class D amplifiers.

### LIST OF ACCOMPANYING DRAWINGS

In order for the present invention to be fully understood and put into practice by any person skilled in this technological sector, it is now described in a clear, precise and sufficient way, based on the accompanying drawings listed below, illustrating preferred ways of carrying out the electronic amplification system:

FIG. 1—electrical circuit of the sound amplification system of the invention;

FIG. 2—Simplified electrical circuit of class H sound amplification system;

FIG. 3—audio signal variation graph in Class G amplifiers;

FIG. 4—electrical circuit of the class D sound amplification system;

FIG. 5a—graph of the variation of the voltage signal of the power supply based on the output signal of the amplifier of the invention when in stand-by, in schematic form;

FIG. 5b—graph of the variation of the voltage signal from the power supply based on the output signal of the amplifier of the invention when in operation, in schematic form.

### DETAILED DESCRIPTION OF THE INVENTION

In order to solve the problems of the current state of the art, which requires several power supplies, as in class H amplifiers, or a variable voltage source of high cost and nominal power higher than the conventional, by not allowing the use of a capacitor with high capacitance in its output, as in class G amplifiers, the present invention is detailed.

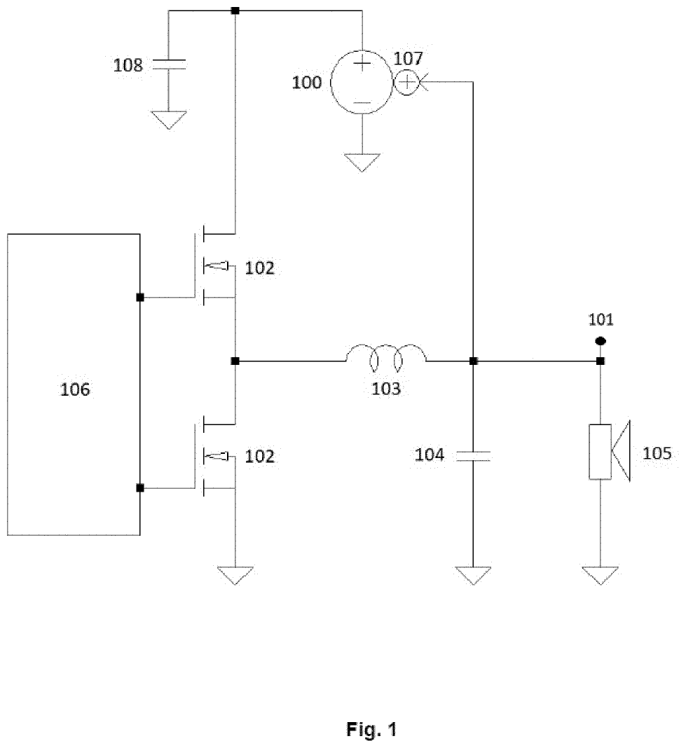

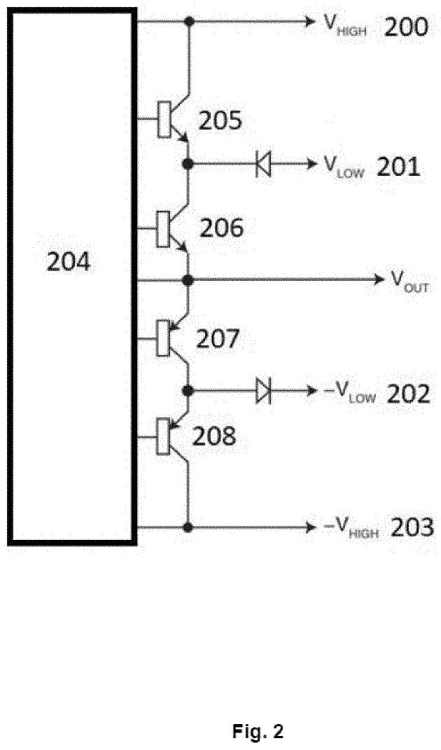

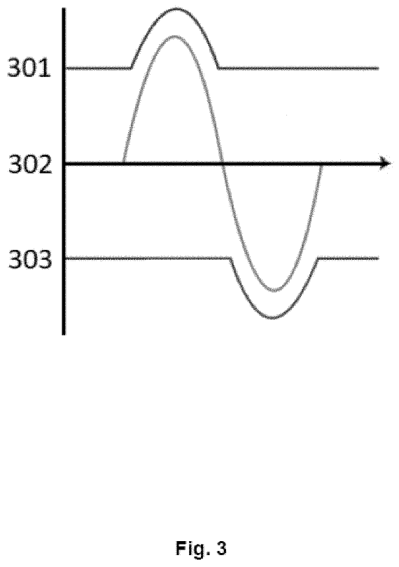

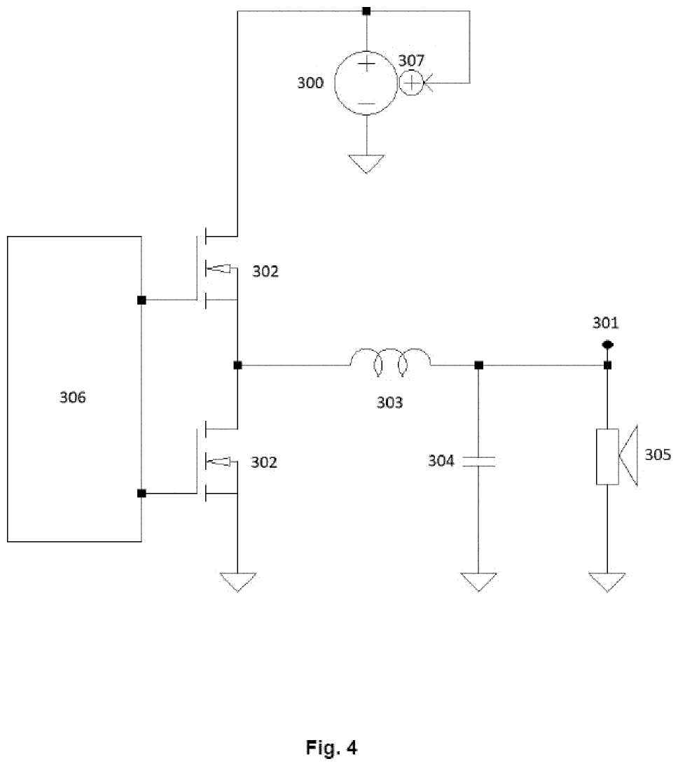

A power supply with variable voltage (100), fed back by the audio signal (107), but with slow rate of variation, allowing the use of a capacitor (108) with high capacitance, as used in conventional low-cost sources and is inserted in the circuit schematized in FIG. 1, whose function is to deliver energy quickly and constantly to the amplifier, greatly improving its audio performance, especially in the low-frequency audio spectrum, solving the problem of the current state of the art that does not allow high capacitance in the output of the source due to the need for a rapid variation of its voltage as occurs with class G amplifiers, at the same time eliminates the need for various power supplies used in class H amplifiers. The power supply voltage (100) remains continuous and always above the maximum voltage of the audio signal of the amplifier output. The amplification system also comprises mosfet transistors (102) connected to a control circuit (106) and the output filter, composed of an inductor (103) and a capacitor (104). The amplifier output (101) involves the filter and a speaker (105).

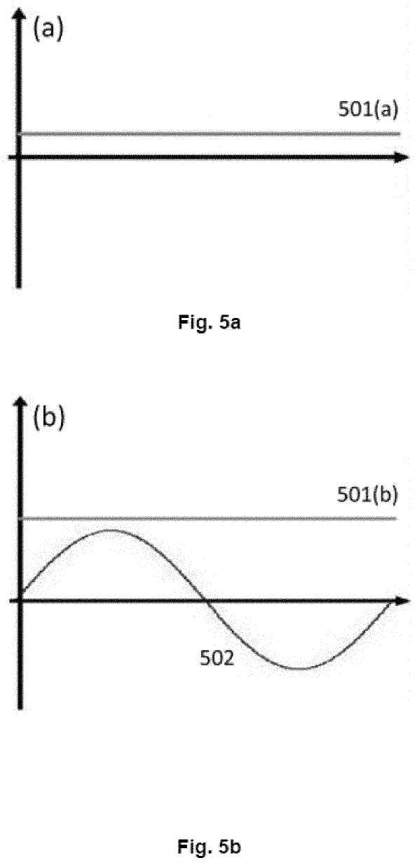

When in stand-by, that is, when the amplifier output signal is null or minimal, the voltage [501(a)] of the power supply (100) is minimal, reducing the energy consumption of the amplifier components, as shown in FIG. 5a. When in operation the audio signal increases in intensity, the voltage [501(b)] of the power supply (100) remains above the maximum peak voltage of the audio signal (502), in order to maintain the correct operation of the amplifier and with minimal waste of energy. If the audio signal increases further in intensity, the power supply voltage (100) rises in order to always be higher than the peak voltage of the audio signal. Thus, regardless of the voltage level of the amplifier output (101), which generates the audio sent to the speaker (105), the power supply (100) remains dynamically in constant variation, reducing the dissipated energy in the amplifier output components.

### COMPARATIVE TESTS BETWEEN THE AMPLIFIERS OF THE STATE OF THE ART AND THE PRESENT INVENTION

In order to show the technical effect achieved by the present invention, comparative stand-by heating tests (without signal), heating during 1 hour of use and stand-by consumption (without signal) were carried out on amplifiers from the state of the art and the present invention.

The stand-by heating test was performed for one hour, without audio, with nominal load at the purely resistive output and 14.4 V at the input. The amplifier from the current state of the art showed heating of 15.9° C., while the amplifier of the present invention showed heating of 0.9° C. Table 1 shows the start and end temperatures of the amplifiers, as well as the differences in the start and end temperatures.

TABLE 1
COMPARATIVE STAND-BY HEATING TEST.

Temperature

| Time | State of the art | Present invention |
|---|---|---|
| Start (t = 0) | 22° C. | 27° C. |
| End (t = 1 hour) | 37.9° C. | 27.9° C. |
| Difference | 15.9° C. | 0.9° C. |

The heating test for 1 hour of use was done with purely resistive load at twice the impedance of the product (2Q), in maximum nominal voltage at the output (55 V AC) with musical signal. Simulating the normal operation of the amplifier, the product from the state of the art underwent an increase in temperature of 66.7° C., while the product with the improvements proposed in the present invention showed an increase of 28.5° C., proving the improvement in efficiency. Table 2 shows the evolution of the temperature of the amplifiers over time, as well as the differences in the start and end temperatures.

TABLE 2
COMPARATIVE HEATING TEST OF
THE AMPLIFIERS IN OPERATION.

Temperature, ° C.

| Time, min | State of the art | Present invention |
|---|---|---|
| t = 0 (start) | 24.1 | 25.1 |
| t = 10 | 77.9 | 49.1 |
| t = 20 | 87.6 | 51.0 |
| t = 30 | 88.4 | 51.4 |
| t = 40 | 88.6 | 52.0 |
| t = 50 | 89.1 | 53.1 |
| t = 60 | 90.8 | 53.6 |
| Difference | 66.7 | 28.5 |

The stand-by consumption test was performed on the connected amplifiers and without audio, with voltage at the input of 14.4 V. The amplifier from the current state of the art presented consumption of 0.945 A without signal at the output, while the amplifier of the present invention presented consumption of 0.451 A, which represents a reduction of around 50% of the current consumed without signal. Table 3 shows the currents consumed for the two amplifiers in stand-by mode.

TABLE 3
Comparative test of current consumption of amplifiers

Current consumed, A

| State | State of the art | Present invention |
|---|---|---|
| Switched off | 0.001 | 0.001 |
| Switched on (silent) | 0.945 | 0.451 |

This specification refers to an electrical audio amplification system, equipped with feedback, whose voltage generated by the power supply is dependent on the magnitude of the amplifier output signal. This composition results in a new technical effect in relation to the state of the art, thus proving its novelty, inventive step, descriptive sufficiency [full disclosure] and industrial application, meeting all the requirements for grant of a patent of invention.

What is claimed is:

1. An efficiency-enhancing system in audio amplifiers comprising a variable power supply, mosfet transistors connected in series to each other and in parallel with an output filter, a control circuit connected in series to said mosfet transistors, wherein said output filter is composed of an inductor and a capacitor connected in parallel, and a speaker connected in parallel to said output filter, characterized in that:
said variable power supply is fed back by the audio signal via a feedback component) and
a high-impedance capacitor is connected in parallel to said variable power supply and to said mosfet transistors.

2. A method for enhancing efficiency in audio amplifiers comprising the steps of:
establishing a variable power supply signal feedback with the audio signal coming from an amplifier output;
dynamicly adjusting of the voltage of said variable power supply to a value above the maximum voltage of the amplifier output audio signal.
